(19) United States
(12) Patent Application Publication
(10) Pub. No.: US 2005/0220221 A1
(43) Pub. Date: Oct. 6, 2005

(54) Identifying a local device by name

(75) Inventors: Raphael Grignani, Helsinki (FI); Michael Josenhans, Tubingen (DE); Tuula Varis, Halikko (FI); Jussi Hamalainen, Salo (FI)

Correspondence Address: HARRINGTON & SMITH, LLP, 4 RESEARCH DRIVE, SHELTON, CT, 06484-6212, US

(73) Assignee: Nokia Corporation

(21) Appl. No.: 11/087,220

(22) Filed: Mar. 22, 2005

(30) Foreign Application Priority Data
Mar. 31, 2004 (GB) 0407247.6

(51) Int. Cl. H03K 9/00

(52) U.S. Cl. 375/316

(57) ABSTRACT

A method for identifying a local device by name, comprising including: storing a database that associates a plurality of device identifiers with a plurality of respective device names; wirelessly obtaining a device identifier of at least one local device from the at least one device; and using the stored database to determine the name of the at least one device.

### FIELD OF THE INVENTION

Embodiments of the present invention relate to identifying a local device by name. In particular, certain embodiments relate to modification of the Bluetooth device discovery and device naming procedures.

### BACKGROUND TO THE INVENTION

A Bluetooth piconet is one form of low power radio frequency communication network. The network has a star topology with a Master device at the centre and one or more Slave devices that separately communicate with the Master. The Master can transmit radio packets to any of the Slaves but a Slave can only transmit radio packets to the Master.

Each radio packets transmitted in the piconet begins its transmission in a different slot and the slot number determines the frequency at which the packet is transmitted. The Master begins transmission in an even number slot and the addressed Slave replies in the next odd numbered slot.

The Master device controls the piconet. The Bluetooth Device Address (BD_ADDR) of the Master determines the frequency hopping sequence used by the piconet and the Bluetooth clock (CLK) of the Master determines the timing used by the piconet. The packets sent within the piconet use a common access code based upon the BD_ADDR of the Master.

A device performs ‘device discovery’ in order to discover other devices with which the device can communicate. The device enters an inquiry sub-state in which it repeatedly transmits an inquiry message (ID packet) at different hop frequencies. A device that allows itself to be discovered regularly enters an inquiry scan sub-state, in which it can respond to inquiry messages with an FHS packet that includes its Bluetooth Device Address (BD_ADDR) and its Bluetooth Clock value (CLK).

In a first phase of establishing a piconet, the Master discovers which devices are within communication range and able to communicate. The Master then uses the Bluetooth Clock value of a local device to emulate its Bluetooth clock and uses the local device's Bluetooth Device Address to emulate the frequency hopping sequence of that device. This allows the Master to page that device and join it to the network as a Slave. The page provides the BD_ADDR of the Master and the CLK of the Master to the Slave, so that the Slave can recreate the frequency hopping sequence of the piconet and emulate the timing of the piconet. A communication link can be established between the Master and Slave after LMP pairing. LMP pairing authenticates the two devices and creates a common link key that is secret and can be used as a basis for a trusted relationship or a single secure connection. After pairing connection can be fully established and the Master and Slave can communicate.

Although the information received in the FHS packet identifies a discovered device using its BD_ADDR it does not identify it in a user-friendly way as the Bluetooth address is a unique 48 bit address. The Name Discovery procedure has therefore been introduced.

This procedure enables a device to discover a user friendly name of a target device, which has replied to an inquiry, without performing the full link establishment procedure. In the name discovery process, the Master initially pages the target device, then it sends a LMP_name_req message and the target device responds with an LMP_name_res message. This message contains the target device's Bluetooth Device Name, which is a user-friendly character string associated with the target device.

The inquiry procedure typically takes 10.24 seconds to complete, at the end of which a device has a list of discovered Bluetooth Device Addresses and Bluetooth Clock values.

The device can then start the Name Discovery procedure to identify the user friendly names of the discovered devices. The Name Discovery procedure can take many seconds, but the end result is a list of Bluetooth Device Names. The user can then select a device from this list with which to establish a link. However, it can take a long time to create this list and then display it to a user, which is frustrating for the user.

It is possible for the inquiry procedure to be shorter than 10.24 seconds. One way of providing more prompt feedback to the user is to interleave the inquiry and paging procedures. When the device discovers a Bluetooth device during the Device Discovery procedure, it stops the Device Discovery procedure and starts the Name Discovery procedure for the discovered device. When the name of that device is discovered, the Name Discovery procedure is stopped, the name of the discovered device is displayed and the Device Discovery procedure is restarted. Although this method provides more prompt feedback to a user, the total time required to discover the names of all the local devices increases.

It would be desirable to provide a fast way of identifying to a user a local device by its name.

### BRIEF DESCRIPTION OF THE INVENTION

According to one embodiment of the invention there is provided a method for identifying a local device by name, comprising: storing a database that associates a plurality of device identifiers with a plurality of respective device names; wirelessly obtaining a device identifier of at least one local device from the at least one device; and
using the stored database to determine the name of the at least one device.

According to another embodiment of the invention there is provided a method of identifying a local device by name for user selection, comprising: initiating a device discovery procedure to discover local devices; displaying, after one of the local devices responds wirelessly during the device discovery procedure, the name of the one local device for user selection; and terminating the device discovery procedure if the user selects the named device.

According to another embodiment of the invention there is provided a wireless telecommunications device for identifying by name another, local wireless telecommunications device, comprising: a memory for storing a database for associating a plurality of device identifiers with a plurality of respective device names;
a radio transceiver for communicating wirelessly with the another local wireless telecommunications device to obtain a device identifier of the another local wireless telecommunications device; and access means for accessing the memory using at least a portion of the device identifier of the another local wireless device to retrieve the device name of the another local wireless telecommunications device.

According to another embodiment of the invention there is provided a wireless telecommunications device for identifying by name another, local wireless telecommunications device, comprising: a memory for storing a database for associating a plurality of device identifiers with a plurality of respective device names;
a radio transceiver for communicating wirelessly, during a device discovery procedure, with a plurality of local wireless telecommunications device to obtain their device identifiers; a display; a controller for controlling the display to display, for user selection, the name of a local device that responds wirelessly during the device discovery procedure; and a user input means for actuation by a user when making a selection.

Embodiments of the invention provide a faster way of identifying to a user the local devices by their names. A local device is one that is within communication range.

### BRIEF DESCRIPTION OF THE DRAWINGS

For a better understanding of the present invention reference will now be made by way of example only to the accompanying drawings in which:

FIG. 1A illustrates a modified device discovery procedure;

FIGS. 1B and 1C illustrate a modified name discovery procedure;

FIG. 1D illustrates link establishment after user selection;

FIGS. 2A, 2B and 2C illustrate the display content during the modified device discovery procedure

FIGS. 3A and 3B illustrate the display content during the modified name discovery procedure of FIG. 1B;

FIG. 4A illustrates the display content during the modified name discovery procedure of FIG. 1C

FIG. 5A schematically illustrates the Found Device Database;

FIG. 5B schematically illustrates the Known Device (Name) Database;

FIG. 6 schematically illustrates a wireless telecommunications device suitable for carrying out the modified device discovery procedure and modified device naming procedure.

### DETAILED DESCRIPTION OF EMBODIMENTS OF THE INVENTION

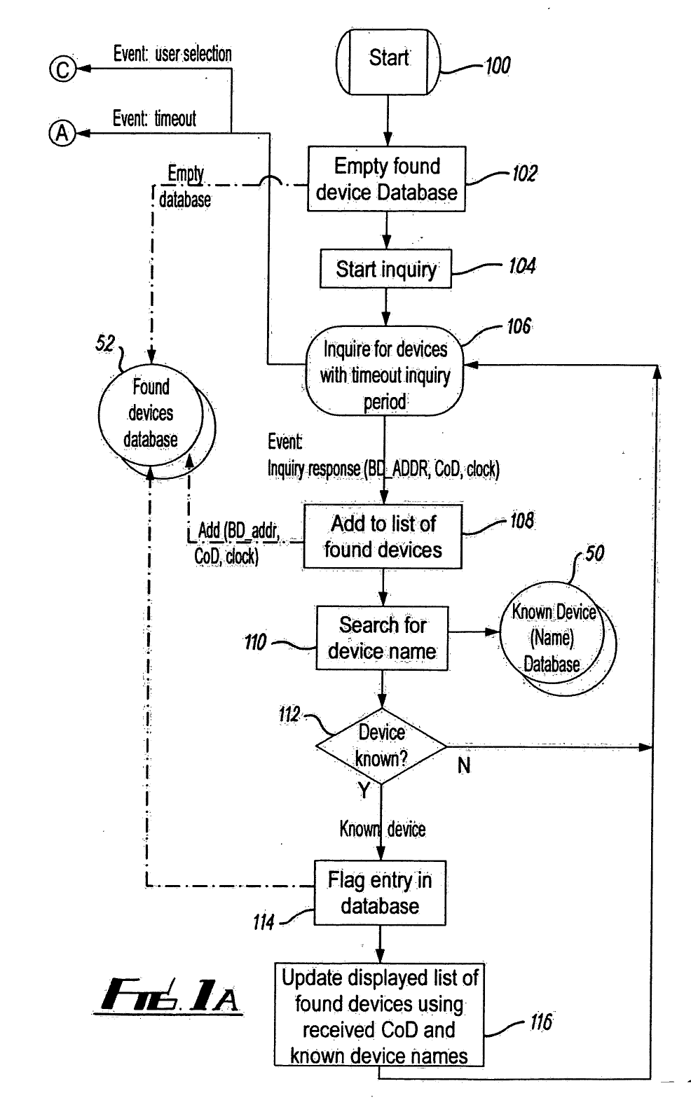

FIGS. 1A, 1B, 1C and 1D illustrate the process by which a user of one Bluetooth device can identify by name another local Bluetooth device and, should they wish, make a communication link to that device by selecting the named device.

A local device may be identified by name by: storing a database (Konwn Device (Name) Database) that associates a plurality of device identifiers (BD_ADDR) with a plurality of respective device names (Bluetooth Device Names); wirelessly obtaining a device identifier (BD_ADDR) of at least one local device from the at least one device; and using the stored database to determine the name (Bluetooth Device Address) of the at least one device. Typically, but not necessarily, the name is then displayed.

Local devices may be identified by name for user selection by: initiating a device discovery procedure to discover local devices; displaying, after one of the local devices responds wirelessly during the device discovery procedure, the name (Bluetooth Device Name) of the one local device for user selection; and terminating the device discovery procedure if the user selects the named device. Typically, but not necessarily, the user selection also initiates link establishment with the selected device.

In this way a list of the names of contactable local devices can be displayed and contemporaneously updated during a modified device discovery procedure using the database. As each new device identifier is received during device discovery, the database is accessed and if an associated device name can be retrieved it is displayed. If the device discovery procedure finishes without user termination, a modified name discovery procedure is performed for each device that responded with its device identifier during device discovery but did not have its name displayed.

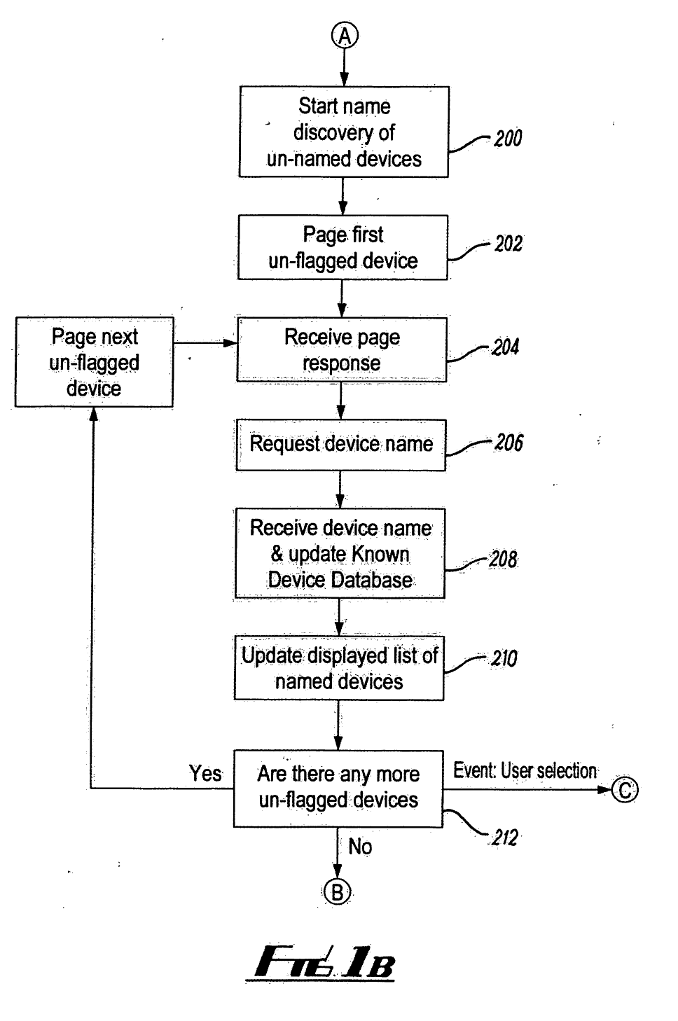

The details of the modified device discovery procedure is illustrated in FIG. 1A and the information that is displayed during that procedure is illustrated in FIGS. 2A, 2B and 2C.

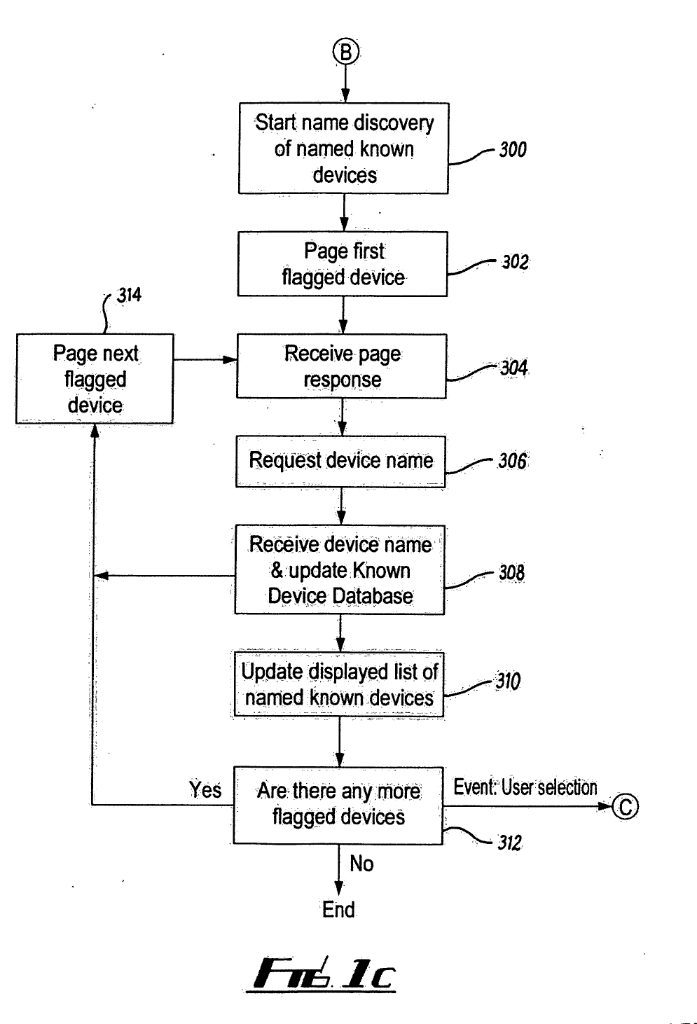

The details of the modified name discovery procedure is illustrated in FIG. 1B and the information that is displayed during that procedure is illustrated in FIGS. 3A and 2B.

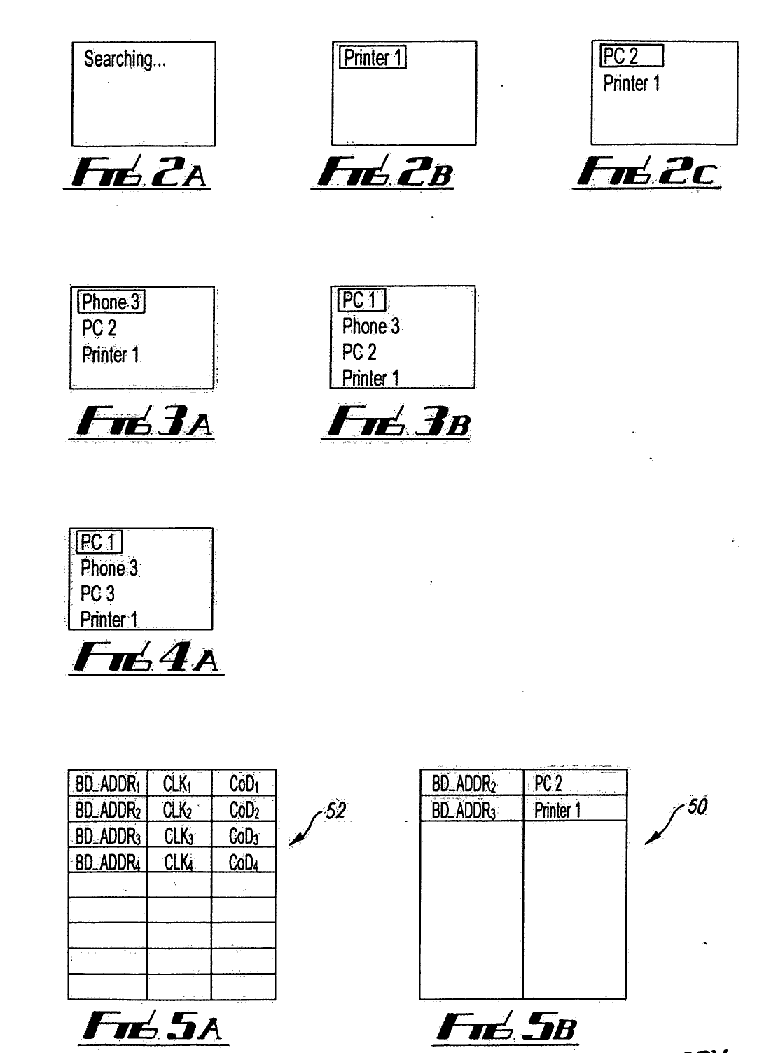

In more detail FIG. 1 illustrates a modified device discovery procedure that uses a new database 50 that associates previously acquired Bluetooth Device Names with their corresponding Bluetooth Device Addresses. The database 50 is schematically illustrated in FIG. 5B as is hence forth referred to as the Known Device (Name) Database.

The process additionally uses a database 52 that stores the information from the FHS packets received from local devices during the device discovery procedure. Such a database is not new as it is used to store the information for paging a device—its Bluetooth Device Address (BD_ADDR) and its Bluetooth Address (BD_ADDR). It also stores the Class of Device (CoD). The database 52 is schematically illustrated in FIG. 5a and is henceforth referred to as the Found Device database.

The process starts at step 100 and moves to step 102, where the Found Device Database 52 is emptied. The inquiry procedure then starts at step 104. At the next step 106, the inquiry procedure continues until either an FHS packet is received from a discovered device or the ‘Inquiry period’, which is typically 10.24 seconds, is timed out.

If an FHS packet is received the process moves to step 108. If the Inquiry Period is timed out the process of FIG. 1A is exited at ‘A’ and the process of FIG. 1 B is entered at step 200.

At step 108, the Bluetooth Device Address (BD_ADDR), Bluetooth Clock value (CLK) and the Class of Device (CoD) received in the FHS packet are stored in the Found Device Database 52.

In the prior art device discovery procedure, the process would then return to step 106. However, in this modified device discovery procedure the process moves to step 110.

At step 110, the Known Device (Name) Database 50 is accessed using the received Bluetooth Device Address (BD_ADDR). If there is an entry corresponding to this BD_ADDR then the Device Name from that entry is retrieved. If there is no entry corresponding to this BD_ADDR then no device name is retrieved. If the device is known i.e. it has an entry in the Known Device (Name) Database 50 then the process moves to step 114. If the device is not known i.e. it has no entry in the Known Device (Name) Database 50 then the process moves back to step 106.

At step 114, a flag is set in the Found device database against the entry corresponding to the known device. This flag indicates that this found device has been named. The process then moves to step 116, where a contemporaneous list of the names of found and named devices is updated and displayed. The updating adds the name retrieved at step 110 when the Known Device (Name) Database was accessed. The process then moves to step 106.

The steps 106, 108, 110, 112, 114, 116 thus form a loop that contemporaneously updates a displayed list of names each time a local device responds to the Bluetooth inquiry and that device has an entry in the Known Device (Name) Database. As described above, this loop is exited with the ‘Inquiry period’ timeout. It can also be exited if the user selects one of the displayed device names. This exit is identified as ‘C’ and is the entrance to the process of FIG. 1D.

The display content during the modified device discovery procedure is illustrated in FIGS. 2A, 2B and 2C. The content illustrated in FIG. 2A is displayed while the process moves around the loop involving steps 106, 108, 110 and 112. The content illustrated in FIG. 2B is displayed after the process move through steps 114 and 116 for the first time. The content illustrated in FIG. 2B is displayed after the process move through steps 114 and 116 for the second time.

The process of FIG. 1B is entered from ‘A’ in FIG. 1A. FIG. 1B illustrates a modified name discovery procedure in which the devices that are found but as yet un-named are named. The process is initiated at step 200. At the next step 202, the local device corresponding to the first un-flagged entry in the Found Device Database 52 is paged.

At step 204, a page response is received from the target local device. At step 206, a LMP_name_req message is sent to the target local device which responds with an LMP_name_res message. This message contains the target device's Bluetooth Device Name, which is a user-friendly character string associated with the target device. At step 208 the LMP_name_res message is received and the Known Device (Name) Database is updated. A new entry is made for this target device that associates its Bluetooth Device address with its Bluetooth Device Name. Then at step 210, the displayed contemporaneous list of the names of found and named devices is updated. The updating adds the Bluetooth Device Name stored to the Known Device (Name) Database 50. The process then moves to step 212.

At step 212, it is determined if there is a subsequent un-flagged entry in the Found Device Database 52. If there is, the process returns to step 204, where name discovery starts for the next unflagged device in the list. If there are no remaining subsequent unflagged entries in the Found Device Database 52, the process exits via ‘B’ to the process of FIG. 1C.

The steps 204, 206, 208, 210 thus form a loop that names, as yet unnamed, found devices and contemporaneously updates the displayed list of found and named devices. The loop can be exited if the user selects one of the displayed device names. This exit is identified as ‘C’ and is the entrance to the process of FIG. 1D.

The display content during the modified name discovery procedure is illustrated in FIGS. 3A and 3B. The content illustrated in FIG. 3A is displayed after the process move through the step 210 for the first time. The content illustrated in FIG. 3B is displayed after the process move through the step 210 for the second time.

The process of FIG. 1C is entered from ‘B’ in FIG. 1B. FIG. 1C illustrates a modified name discovery procedure in which the names of the devices that were found and named during device discovery are updated. The process is initiated at step 300. At the next step 302, the target local device corresponding to the first flagged entry in the Found Device Database 52 is paged. At step 304, a page response is received from the target local device.

At step 306, a LMP_name_req message is sent to the target local device, which responds with an LMP_name_res message. This message contains the target device's Bluetooth Device Name, which is a user-friendly character string associated with the target device. At step 308 the LMP_name_res message is received.

If the Bluetooth Device Name received in this message is the same as the device name stored in the Known Device (Name) database for this target device, then the process moves to step 314, where the next flagged device is paged.

If the Bluetooth Device Name received in this message is different to the device name stored in the Known Device (Name) database for this target device, then the Known Device (Name) Database is updated. A replacement entry is made for this target device that associates its Bluetooth Device address with its new Bluetooth Device Name. Then at step 310, the displayed contemporaneous list of the names of found and named devices is updated. The updating either replaces the old Bluetooth Device Name with the new Bluetooth Device Name or adds the new Bluetooth Device Name to the list. The process then moves to step 312.

At step 312, it is determined if there is a subsequent flagged entry in the Found Device Database 52. If there is, the process returns to step 314, where name discovery starts for the next flagged device. If there are no remaining flagged entries in the Found Device Database 52, the process ends.

The steps 304, 306, 308, 310, 312, 314 thus form a loop that updates the names of previously found and named devices and contemporaneously updates the displayed list of found and named devices. The loop can be exited if the user selects one of the displayed device names. This exit is identified as ‘C’ and is the entrance to the process of FIG. 1D.

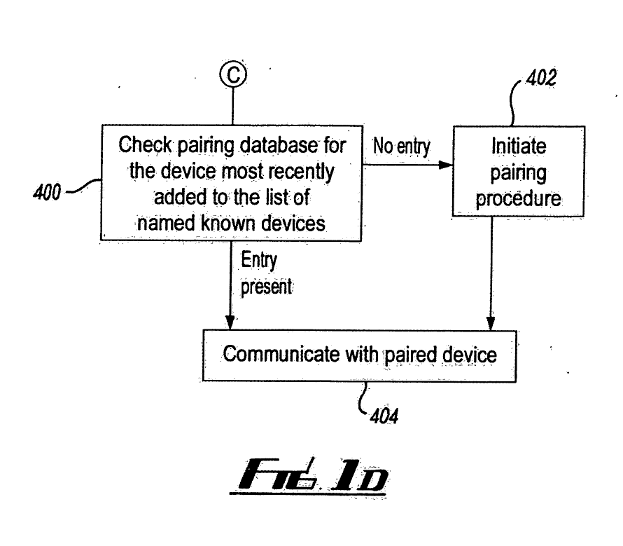

The display content during this modified name discovery procedure is illustrated in FIG. 4A. The content illustrated in FIG. 4A is displayed after the process moves through the step 310 for the first time. The name ‘PC 2’ is updated to ‘PC3’.

FIG. 1D illustrates the process of link establishment with a device selected by the user from the contemporaneously displayed list of found and named devices. At step 400, a pairing database is checked to see if a link key already exists for the selected device. If a link key exists, a link is established at step 204. If a key does not exist, a key is created at step 402 using a pairing procedure. The key is then used for authentication.

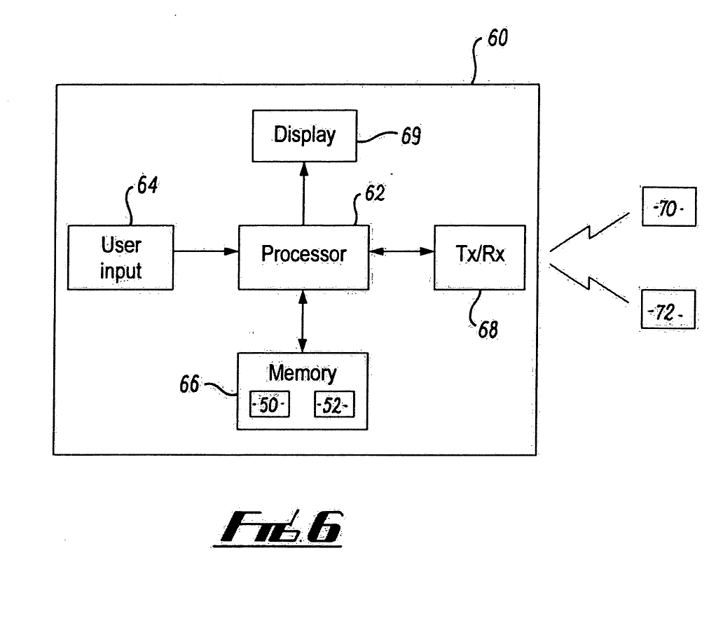

FIG. 6 schematically illustrates a wireless telecommunications device 60 that is capable of performing the above described methods. In this example, the wireless telecommunications device is Bluetooth enabled. The device 60 comprises a processor 62, a user input mechanism 64, a memory 66, a low power radio frequency transceiver 68 and a display 69.

The processor 62 controls the operation of the device 60. It receives an input from the user input mechanism 64 and an input from the LPRF transceiver 68 and it provides an output to the LPRF transceiver 68 and controls the display 69. The processor 66 can also write to and read from the memory 66.

The device 60 may be a hand portable electronic device such as a mobile cellular telephone. The user input mechanism may be any suitable mechanism such as a key, a joy-stick, a dial or a microphone for voice commands. The memory 66 stores the Known Device (Name) database 50 and the Found Device Database 52. The LPRF transceiver 68 is able to communicate with other local wireless telecommunication devices 70, 72. These devices are local to the device 60 in the sense that they are within communication range of the device 60, which may, for example, be of the order of 10 to 100 m.

At step 108 in FIG. 1A, after the LPRF transceiver 68 receives an FHS packet during device discovery, the processor 62 writes the BD_ADDR, CLK and CoD to the Found device database 52.

At step 110 in FIG. 1A, the processor 62 accesses the Known Device (Name) Database 50 in the memory 66 using at least a portion of a device identifier and retrieves the device name.

At step 114 in FIG. 1A the processor 62 writes a flag to the Found device database 52.

At step 116 in FIG. 1A the processor 62 controls the display 69 to update the displayed list of found and named devices.

The processor 62 also detects user actuation of the user input mechanism 64 and controls the exit ‘C’ from the modified device discovery procedure at step 106, and from the modified name discovery procedure at steps 212 and 312.

Although embodiments of the present invention have been described in the preceding paragraphs with reference to various examples, it should be appreciated that modifications to the examples given can be made without departing from the scope of the invention as claimed. For example, although the Known Device (Name) Database is described as associating Bluetooth Device Addresses with Bluetooth device names, in other embodiments only a portion of the Bluetooth Device Address may be associated with the respective Bluetooth Device name. The Known Device (Name) database may be a database that is independent of a database of previously paired devices or it may be integrated with the database of previously paired devices. It should be appreciated that the modified device discover procedure may be performed without the modified device naming procedure following it. In this case, the Known Device (Name) database may be replaced with a database of previously paired devices.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

1. A method for identifying a local device by name, comprising: storing a database that associates a plurality of device identifiers with a plurality of respective device names; wirelessly obtaining a device identifier of at least one local device from the at least one device; and using the wirelessly obtained device identifier to determine the name of the at least one device from the stored database.

2. A method as claimed in claim 1, further comprising displaying the determined name of the at least one device.

3. A method as claimed in claim 1, wherein the device identifier is an address and the database associates, for each of a plurality of devices, an address or a portion of an address with a device name.

4. A method as claimed in claim 2, further comprising obtaining the device identifiers of a plurality of local devices and using the stored database to determine the names of at least some of the local devices.

5. A method as claimed in claim 1, further comprising:
initiating a device discovery procedure to obtain wirelessly the device identifiers of local devices;
determining, after one of the local devices responds wirelessly with its device
identifier during the device discovery procedure, the name of the one local device by using the stored database;
displaying the name of the one user device for user selection; and
terminating the device discovery procedure if the user selects the named device.

6. A method as claimed in claim 5, further comprising, after terminating the device discovery procedure, initiating authentication of the named device.

7. A method as claimed in claim 5, further comprising, if the named device is not selected, determining, after another of the local devices responds wirelessly with its device identifier during the device discovery procedure, the name of the another device using the stored database; displaying the name of the another device for user selection; and terminating the device discovery procedure if the user selects the named another device.

8. A method as claimed in claim 7, further comprising, after terminating the device discovery procedure, initiating authentication of the named another device.

9. A method as claimed in claim 5, further comprising: after the device discovery procedure finishes without user termination, performing a name discovery procedure for each device that responds during the device discovery procedure but does not have its name displayed during the device discovery procedure.

10. A method as claimed in claim 1, further comprising: initiating a device discovery procedure to obtain wirelessly the device identifiers of local devices;
displaying, as soon as each local device responds wirelessly with its device identifier during the device discovery procedure, the name of the responding local device if its is in the stored database.

11. A method as claimed in claim 10, further comprising:
after the device discovery procedure finishes, performing a name discovery procedure for each device that responds during device discovery but does not have its name in the stored database.

12. A method as claimed in claim 5, wherein the device discovery procedure involves the Bluetooth inquiry procedure.

13. A method as claimed in claim 1, wherein the device identifier is an address.

14. A method as claimed in claim 13, wherein the address is a Bluetooth Device address.

15. A method of identifying a local device by name for user selection, comprising:
initiating a device discovery procedure to discover a plurality of local devices; displaying, after one of the local devices responds wirelessly during the device discovery procedure, the name of the one local device for user selection;
terminating the device discovery procedure if the user selects the named device; and
continuing with the device discovery procedure if the user does not select the named device.

16. A method as claimed in claim 15, further comprising: displaying, after another of the local devices responds during the device discovery procedure, the name of the another device for user selection; and terminating the device discovery procedure if the user selects the named another device.

17. A method as claimed in claim 15, further comprising: after the device discovery procedure finishes without user termination, performing a name discovery procedure for each device that responds wirelessly during device discovery but does not have its name displayed during device discovery.

18. A wireless telecommunications device for identifying by name another, local wireless telecommunications device, comprising:
a memory for storing a database for associating a plurality of device identifiers with a plurality of respective device names;
a radio transceiver for communicating wirelessly with the another local wireless telecommunications device to obtain a device identifier of the another local wireless telecommunications device; and
access means for accessing the memory using at least a portion of the device identifier of the another local wireless device to retrieve the device name of the another local wireless telecommunications device.

19. A wireless telecommunications device as claimed in claim 18, further comprising a display and a controller for controlling the display to display the retrieved name of the another local wireless telecommunications device.

20. A wireless telecommunications device as claimed in claim 18, wherein the obtained device identifier is an address used by the radio transceiver to communicate with the another local wireless telecommunications device and the database associates, for each of the plurality of devices, an address or a portion of an address with a respective device name.

21. A wireless telecommunications device as claimed in claim 20, wherein the radio transceiver is operable to communicate wirelessly with a plurality of local wireless telecommunications devices to obtain a plurality of device identifiers and the access means is operable to access the memory using at least a portion of each device identifier as each device identifier is obtained by the radio transceiver.

22. A wireless telecommunications device as claimed in claim 18, further comprising:
a user input means, a display and a controller for controlling the display to display the retrieved name of the another local wireless telecommunications device, wherein the wireless telecommunications device is responsive to selection, using the user input means, of the displayed name to terminate any on-going device discovery procedure in which the radio transceiver communicates wirelessly with a plurality of local wireless telecommunications devices to obtain a plurality of identifiers.

23. A wireless telecommunications device as claimed in claim 22, being further responsive to the user selection of the displayed name to initiate authentication of the wireless telecommunication device corresponding to the selected displayed name.

24. A wireless telecommunications device as claimed in claim 22, wherein, in the absence of actuation of the user input means to select the displayed name, the radio transceiver is operable to obtain a device identifier of a further local wireless telecommunications device;
the access means is operable to access the memory using at least a portion of the deice identifier of the further local wireless device to retrieve the name of the further local wireless telecommunications device;
the controller is operable to control the display to display the name of the further local wireless telecommunications device if retrievable from the database; and
the wireless telecommunications device is responsive to selection, using the user input means, of a displayed name to terminate any on-going device discovery procedure in which the radio transceiver communicates wirelessly with a plurality of local wireless telecommunications devices to obtain a plurality of device identifiers.

25. A wireless telecommunications device as claimed in claim 24, being further responsive to the user selection of the displayed name to initiate authentication of the wireless telecommunication device corresponding to the selected displayed name.

26. canceled

27. A wireless telecommunications device as claimed in claim 21, further comprising:
a user input means, a display and a controller for controlling the display to display the names retrieved by the database during a device discovery procedure in which the radio transceiver communicates wirelessly with a plurality of local wireless telecommunications devices to obtain the plurality of device identifiers , wherein,
after the device discovery procedure finishes the wireless communication device is operable to perform a name discovery procedure for each device that responded during device discovery but has not have its name displayed during the device discovery procedure.

28. A wireless telecommunications device as claimed in claim 18, wherein a device identifier is an address.

29. A wireless telecommunications device as claimed in claim 28 wherein the address is a Bluetooth Device address.

30. A wireless telecommunications device for identifying by name another, local wireless telecommunications device, comprising:
a memory for storing a database for associating a plurality of device identifiers with a plurality of respective device names;
a radio transceiver for communicating wirelessly, during a device discovery procedure, with a plurality of local wireless telecommunications device to obtain their device identifiers;
a display;
a controller for controlling the display to display, for user selection, the name of a local device that responds wirelessly during the device discovery procedure; and
a user input means for actuation by a user when making a selection.

31. canceled
